(19) United States
(12) Patent Application Publication
(10) Pub. No.: US 2024/0372054 A1
(43) Pub. Date: Nov. 7, 2024

(54) OPTOELECTRONIC APPARATUS AND OPTOELECTRONIC SEMICONDUCTOR DEVICE

(71) Applicant: ams-OSRAM International GmbH, Regensburg (DE)

(72) Inventors: Tansen Varghese, Regensburg (DE); Andreas Lex, Zandt (DE); Adrian Avramescu, Regensburg (DE)

(21) Appl. No.: 18/683,895

(22) PCT Filed: Aug. 30, 2022
(86) PCT No.: PCT/EP2022/074101

§ 371 Date: Feb. 15, 2024

(30) Foreign Application Priority Data
Sep. 7, 2021 (DE) 10 2021 123 119.1

(51) Int. Cl. H01L 33/62; H01L 25/075; H01L 33/60

(52) U.S. Cl. CPC H01L 33/62; H01L 25/0753; H01L 33/60

(57) ABSTRACT

In an embodiment an optoelectronic semiconductor device includes a semiconductor layer stack having a first semiconductor layer of a first conductivity type, an active zone, and a second semiconductor layer of a second conductivity type, wherein the optoelectronic semiconductor device is configured to emit generated electromagnetic radiation via a first main surface of the first semiconductor layer, and wherein a lateral width z of the active zone is smaller than a smallest lateral width c of the first and the second semiconductor layers, separating elements arranged adjacent to the semiconductor layer stack, the separating elements vertically extending along the semiconductor layer stack, and portions of a metal layer arranged on a side of the first semiconductor layer facing away from the active zone and arranged at positions of the separating elements.

### CROSS-REFERENCE TO RELATED APPLICATIONS

This patent application is a national phase filing under section 371 of PCT/EP2022/074101, filed Aug. 30, 2022, which claims the priority of German patent application 10 2021 123 119.1, filed Sep. 7, 2021, each of which is incorporated herein by reference in its entirety.

### TECHNICAL FIELD

Displays, e.g. for augmented or virtual reality applications comprise arrays or miniaturized LEDs (“Light Emitting Diode”). Efforts are being taken to develop micro LEDs having a light emission with an improved directionality.

### SUMMARY

Embodiments provide an improved optoelectronic apparatus as well as an improved optoelectronic semiconductor device.

According to embodiments, the above objects are achieved by the claimed matter according to the independent claims. Further developments are defined in the dependent claims.

An optoelectronic apparatus comprises an array of optoelectronic semiconductor devices. The optoelectronic apparatus comprises a semiconductor layer stack comprising a first semiconductor layer of a first conductivity type, an active zone, and a second semiconductor layer of a second conductivity type. Adjacent optoelectronic semiconductor devices are separated by separating elements vertically extending through the semiconductor layer stack. The optoelectronic semiconductor devices are configured to emit generated electromagnetic radiation via a first main surface of the first semiconductor layer. The optoelectronic apparatus further comprises portions of a metal layer arranged on a side of the first semiconductor layer facing away from the active zone and being arranged at positions of the separating elements.

According to embodiments, the separating elements comprise a conductive body and an insulating layer insulating the conductive body from the semiconductor layer stack. A largest horizontal extension of the portion of the metal layer is larger than or equal to a smallest horizontal extension of the conductive body.

The metal layer may comprise silver or gold or another suitable reflecting metal.

According to embodiments, the horizontal extension of the portions of the metal layer increases with increasing distance from the first main surface. According to further embodiments, the horizontal extension of the portions of the metal layer decreases with increasing distance from the first main surface.

According to examples, a dielectric layer may be arranged over sidewalls of the portion of the metal layer.

For example, a thickness of the metal layer may be equal to or larger than 0.1*we, where we is a width of an emitting area. Generally, we may correspond to the largest horizontal extension of the first and the second semiconductor layers.

According to further embodiments, an optoelectronic semiconductor device comprises a semiconductor layer stack comprising a first semiconductor layer of a first conductivity type, an active zone, and a second semiconductor layer of a second conductivity type, and separating elements arranged adjacent to the semiconductor layer stack, the separating elements vertically extending along the semiconductor layer stack. The optoelectronic semiconductor device is configured to emit generated electromagnetic radiation via a first main surface of the first semiconductor layer. The optoelectronic semiconductor device further comprises portions of a metal layer arranged on a side of the first semiconductor layer facing away from the active zone and being arranged at positions of the separating elements. A void or a plurality of holes are formed in the first main surface of the first semiconductor layer, a vertical extension v of the void or the plurality of holes being larger than 0.75*t, wherein t denotes a layer thickness of the first semiconductor layer. The depth of individual holes may be different. The shape of the holes in the plan view may be circular, square, rectangular, triangular, hexagonal, etc., and may be different from each other.

According to further embodiments, an optoelectronic semiconductor device comprises a semiconductor layer stack comprising a first semiconductor layer of a first conductivity type, an active zone, and a second semiconductor layer of a second conductivity type. Separating elements are arranged adjacent to the semiconductor layer stack, the separating elements vertically extending along the semiconductor layer stack. The optoelectronic semiconductor device is configured to emit generated electromagnetic radiation via a first main surface of the first semiconductor layer. The optoelectronic semiconductor device further comprises portions of a metal layer arranged on a side of the first semiconductor layer facing away from the active zone and being arranged at positions of the separating elements. A plurality of holes is formed in the first main surface of the first semiconductor layer so that an ordered photonic structure is formed in the first main surface of the first semiconductor layer.

For example, each of the separating elements comprises a conductive body insulated from the semiconductor layer stack by a dielectric layer.

The optoelectronic semiconductor device may further comprise a dielectric filling arranged in the void or in at least one of the plurality of holes.

According to embodiments, the optoelectronic semiconductor device further comprises a transparent conductive oxide material filled in the void or in at least one of the plurality of holes.

For example, the semiconductor layer stack is patterned to form a mesa, an angle of a sidewall of the void with respect to a horizontal direction being smaller than the angle of a sidewall of the mesa with respect to the horizontal direction.

According to examples, the optoelectronic semiconductor device further comprises a reflecting material arranged in at least one of the holes.

By way of example, the reflecting material comprises a dielectric mirror layer arranged on sidewalls of at least one of the holes.

Additionally or alternatively, the reflecting material may comprise a metal.

According to embodiments, an optoelectronic semiconductor device comprises a semiconductor layer stack comprising a first semiconductor layer of a first conductivity type, an active zone, and a second semiconductor layer of a second conductivity type. The optoelectronic semiconductor device is configured to emit generated electromagnetic radiation via a first main surface of the first semiconductor layer. A lateral width z of the active zone is smaller than the smallest lateral width c of the first and the second semiconductor layers.

For example, the lateral width of the active zone is smaller than 0.3*c, wherein c denotes the smallest lateral width of the first semiconductor layer.

The optoelectronic semiconductor device may further comprise a lens arranged above the first main surface of the first semiconductor layer, a focal point of the lens being arranged at a position of the active zone.

According to embodiments, the optoelectronic semiconductor device further comprises separating elements arranged adjacent to the semiconductor layer stack, the separating elements vertically extending along the semiconductor layer stack.

The optoelectronic semiconductor device may further comprise portions of a metal layer arranged on a side of the first semiconductor layer facing away from the active zone and being arranged at positions of the separating elements.

An optoelectronic apparatus comprises an array of optoelectronic semiconductor devices as described above.

The optoelectronic apparatus may further comprise separating elements comprising an insulating material, the separating elements being disposed between the optoelectronic semiconductor devices at a position of the first main surface of the first semiconductor layer and having a vertical extension b smaller than a thickness of the semiconductor layer stack.

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

### BRIEF DESCRIPTION OF THE DRAWINGS

FIGS. 1A to 1C show vertical cross-sectional views of an optoelectronic apparatus according to embodiments;

FIGS. 2A to 2C illustrate cross-sectional views of an optoelectronic apparatus according to further embodiments;

FIGS. 3A to 3C show vertical cross-sectional views of optoelectronic semiconductor devices according to embodiments;

FIGS. 3D and 3E show horizontal cross-sectional views of optoelectronic semiconductor devices according to embodiments;

FIGS. 4A and 4B show cross-sectional views of semiconductor devices according to further embodiments;

FIG. 4C illustrates a further modification of a detail of an optoelectronic semiconductor device;

FIGS. 5A to 5C illustrate cross-sectional views of optoelectronic semiconductor devices according to further embodiments; and

FIGS. 6A and 6B illustrate cross-sectional views of optoelectronic semiconductor devices according to further embodiments.

### DETAILED DESCRIPTION OF ILLUSTRATIVE EMBODIMENTS

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g. supported by a base semiconductor foundation, and other semiconductor structures. For example, a layer of a first semiconductor material may be grown on a growth substrate of a second semiconductor material. According to further embodiments, the growth substrate may be an insulating substrate such as a sapphire substrate. Depending on the purpose of use, the semiconductor may be based on a direct or an indirect semiconductor material. Examples of semiconductor materials particularly suitable for generation of electromagnetic radiation comprise nitride-compound semiconductors, by which e.g. ultraviolet or blue light or longer wavelength light may be generated, such as GaN, InGaN, AlN, AlGaN, AlGaInN, phosphide-compound semiconductors, by which e.g. green or longer wavelength light may be generated such as GaAsP, AlGaInP, GaP, AlGaP, as well as further semiconductor materials including AlGaAs, SiC, ZnSe, GaAs, ZnO, Ga₂O₃, diamond, hexagonal BN und combinations of these materials. Further examples of semiconductor materials may as well be silicon, silicon-germanium and germanium. The stoichiometric ratio of the compound semiconductor materials may vary. In the context of the present specification, the term “semiconductor” further encompasses organic semiconductor materials.

The term “vertical” as used in this specification intends to describe an orientation which is arranged perpendicular to the first surface of a substrate or semiconductor body.

The terms “lateral” and “horizontal” as used in this specification intends to describe an orientation parallel to a first surface of a substrate or semiconductor body. This can be for instance the surface of a wafer or a die.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

The term “electrically connected” further comprises tunneling contacts between connected elements.

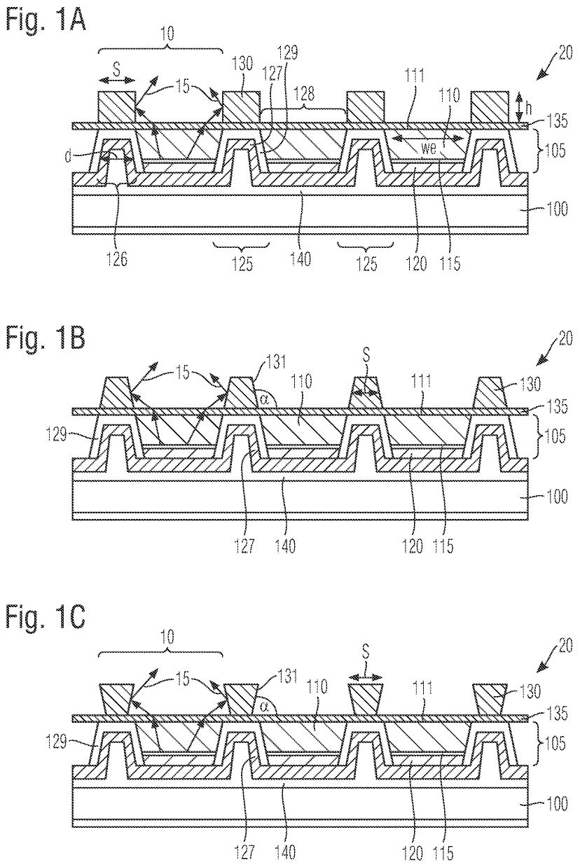

FIG. 1A shows vertical cross-sectional view of an optoelectronic apparatus according embodiments. As will be explained in the following, the optoelectronic apparatus 20 comprises an array of optoelectronic semiconductor devices 10. The optoelectronic apparatus comprises a semiconductor layer stack 105 comprising a first semiconductor layer 110 of a first conductivity type, e.g. n-type, an active zone 115 and a second semiconductor layer 120 of a second conductivity type, e.g. p-type.

The active zone 115 may, for example, comprise a pn junction, a double heterostructure, a single quantum well (SQW) structure or a multi quantum well (MQW) structure for generating radiation. In this context, the term “quantum well structure” has no meaning with regard to the dimensionality of the quantization. Thus, it includes, among other things, quantum wells, quantum wires and quantum dots, as well as any combination of these layers.

Adjacent optoelectronic semiconductor devices are separated by separating elements 125 that vertically extend through the semiconductor layer stack 105. The optoelectronic semiconductor devices 10 are configured to emit generated electromagnetic radiation 15 via a first main surface 111 of the first semiconductor layer 110. The optoelectronic apparatus 20 further comprises portions of a metal layer 130 arranged on a side of the first semiconductor layer 110 facing away from the active zone 115 and being arranged at positions of the separating elements 125.

The optoelectronic apparatus 20 may be arranged over a suitable carrier 100 that may be made of an insulating, conductive or semiconductor material. The separating elements 125 that are arranged between adjacent optoelectronic semiconductor devices may comprise a conductive body 126 and an insulating layer 129 insulating the conductive body 126 from the semiconductor layer stack 105. For example, the conductive body may comprise a separating metal layer 127. The separating metal layer 127 may e.g. comprise a transparent conductive oxide such as ITO (“Indium Tin Oxide”). The separating metal layer 127 may be arranged adjacent to the insulating layer 129. For example, the separating metal layer 127 may extend from a portion beneath the second semiconductor layer 120 to a region above the active zone 115. Horizontal portions of the separating metal layer may be electrically connected to the second semiconductor layer.

A second current spreading layer 140 may be arranged over the carrier 100. The second current spreading layer 140 may be electrically connected to the second semiconductor layer 120 via the separating metal layer 127. Portions of the second current spreading layer 140 may form part of the conductive body 126 of the separating elements 125.

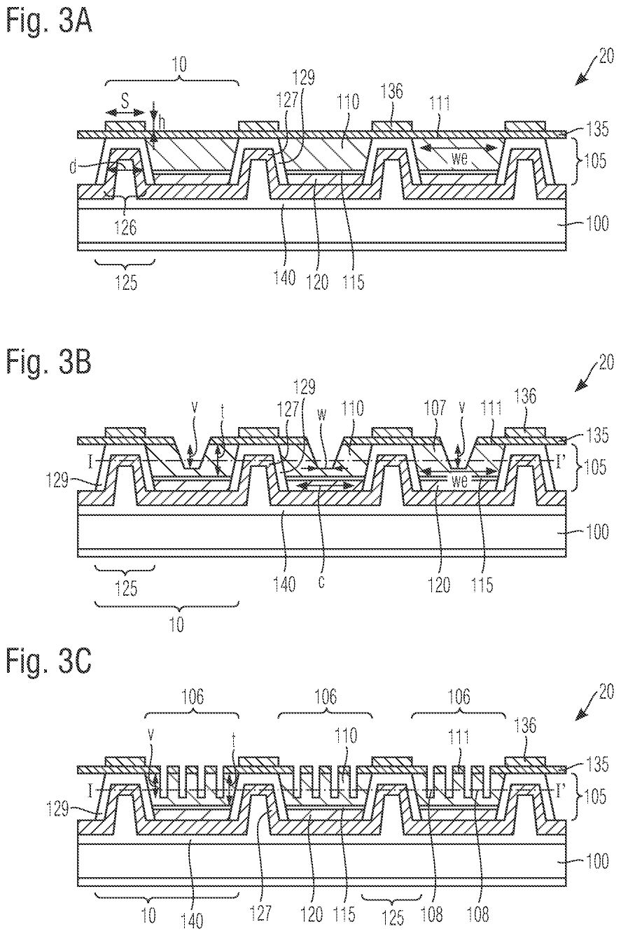

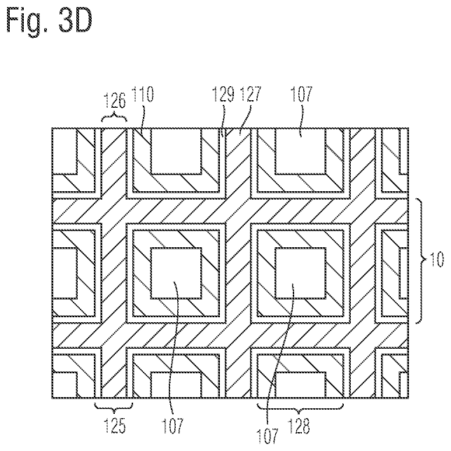

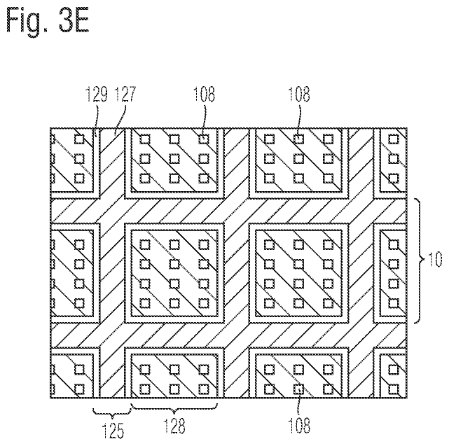

For example, the structure shown in FIG. 1A may be formed by growing the semiconductor layer stack 105 over a growth substrate, so that the first semiconductor layer 110 is adjacent to the growth substrate. Subsequently, separating grooves are formed in the semiconductor layer stack 105. The separating grooves are lined with the insulating layer 129 and the separating metal layer 127. For example, the insulating layer 129 may be removed from portions where the metal layer 127 is in contact with the second semiconductor layer 120. Thereafter, a further metal layer is filled in the remaining portion of the grooves to form part of the conductive body 126 and further the second current spreading layer 140. Due to the formation of the separating grooves, the semiconductor layer stack 105 is patterned to a plurality of single mesas 128. The single mesas 128, in which the optoelectronic semiconductor devices 10 are formed, may e.g. have the shape of a square, a circle, a square having rounded corners, a hexagon or a hexagon having rounded corners. Examples of the single semiconductor devices 10 may be recognized from the horizontal cross-sectional views shown in FIGS. 3B and 3E.

A material of the first and second semiconductor layers 110, 120 may comprise InₓGayAl_{1-x-y}P, with 0≤x≤1, 0≤y≤1, or GaN and InGaN.

The first current spreading layer 135 may be arranged over the first main surface 111 of the first semiconductor layer 110. The separating elements 125 may extend to the first current spreading layer 135. A horizontal upper portion of the insulating layer 129 may be adjacent to the first current spreading layer 135. The first current spreading layer 135 may be made of a transparent material such as a transparent conductive oxide or may as well be part of the first semiconductor layer 110.

Portions of a metal layer 130 are arranged on a side of the first semiconductor layer. For example, the metal layer 130 may comprise a usually employed contact material such as AuGe, PdGe, Ag, Ag, etc. The metal layer 130 may comprise several sub-layers. For example, the metal layer 130 may further comprise a layer of transparent conducting oxide such as ITO below any of these contact materials.

Moreover, a further metal may be formed over the contact layer. The further metal may comprise silver or gold or another metal having a high reflectivity. A horizontal width s of the portion of the metal layer may be larger or smaller than or be equal to a smallest width d of the conductive body 126 of the separating element 126. According to embodiments, the horizontal width s may be larger than or equal to the smallest width d. In this case, a directionality of the emitted electromagnetic radiation may be further improved.

A height h of the portions of the metal layer may be equal to or larger than 0.1*we, where we is the width of the emitting area of the light emitting portions.

For example, a size of the single optoelectronic semiconductor devices 10 may be smaller than 10 μm. As is further illustrated in FIG. 1A, due to the presence of the portions of the metal layer 130, it is possible to shape the beam of emitted electromagnetic radiation 15. Hence, the directionality of the generated electromagnetic radiation is enhanced. The portions of the metal layer 130 may be arranged between the respective mesas 128. According to further embodiments, they may also overlap the mesas to a certain extent.

FIG. 1B shows a vertical cross-sectional view of the optoelectronic apparatus 20 according to further embodiments. The optoelectronic apparatus 20 of FIG. 1B comprises the same or identical components as the optoelectronic apparatus shown in FIG. 1A. Differing from embodiments illustrated in FIG. 1A, the optoelectronic apparatus of FIG. 1B comprises portions of a metal layer 130, wherein the sidewalls of the portions are inclined. As is illustrated in FIG. 1B, the sidewall 131 may have an angle α with respect to the first main surface 111 of the first semiconductor layer 110 that is larger than 90°. Accordingly, a diameter of the metal layer 130 becomes smaller with increasing distance from the first semiconductor layer 110. In this case, the term “largest horizontal extension of the portion of the metal layer” denotes the width s of the portion of the metal layer in a region adjacent to the first semiconductor layer 110. Accordingly, the portions of the metal layer 130 implement a trapezoidal metal grid. For example, the trapezoidal metal grid may be formed by tailoring the slope of a negative photoresist sidewall slope and by using a metal deposition method with better conformity, e.g. planetary e-beam, sputtering or plating. Thereafter, polishing to expose the photoresist may be performed, if necessary, followed by a lift-off process. According to further implementations, this may also be achieved by dry etching and adjusting the dry etch selectivity of a resist material versus that of the metal.

The optoelectronic apparatus 20 of FIG. 1C is identical or comprises identical components as the optoelectronic apparatus illustrated in FIGS. 1A and 1B. Different from embodiments illustrated in FIGS. 1A and 1B, the sidewalls 131 of the metal layer 130 have an angle α with respect to a horizontal plane which is smaller than 90°. In other words, a width s of the portions of the metal layer 130 increases with increasing distance from the first semiconductor layer. In this case, the largest horizontal extension s of the portion of the metal layer 130 is arranged on a side facing away from the first semiconductor layer 110.

Accordingly, the portions of the metal layer 130 implement an inverse trapezoidal metal grid. The inverse trapezoidal metal grid which is illustrated in FIG. 1C may be formed by tailoring a positive photoresist sidewall slope, depositing metal and by removing the metal on top by polishing until the photoresist has been reached. Thereafter, the remaining photoresist material is removed by standard resist stripping methods.

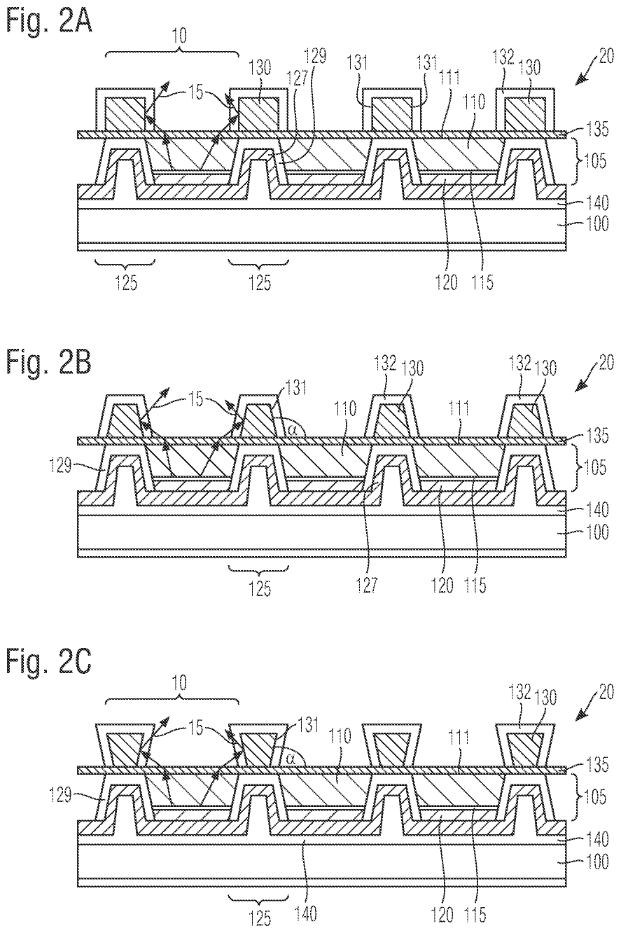

The optoelectronic apparatus 20 of FIG. 2A comprises the same or identical components as the optoelectronic apparatus 20 shown in FIG. 1A. In addition, portions of a dielectric layer 132 are formed over the portions of the metal layer 130 so as to cover the sidewalls 131 as well as the top portion of the metal layer 130. As a result, the portions of the metal layer 130 are encapsulated by the dielectric layer 132. Due to the presence of the dielectric layer 132, absorption of the emitted electromagnetic radiation 15 by the metal layer 130 may be reduced.

For example, the dielectric layer 132 may comprise a dielectric mirror. Generally, a dielectric or DBR mirror may comprise first layers of a first composition and second layers of a second composition which are alternately stacked. The first and the second layers may be dielectric layers. For example, the first layers may have a high refractive index and the second layers may have a low refractive index. In this context, the terms “high refractive index” and “low refractive index” may mean that the high refractive index is larger than a certain value that may depend on the material system. The low refractive index is smaller than the certain value.

For example, the layer thickness may be approximately λ/4 or a multiple of λ/4, wherein λ denotes the wavelength of the light to be reflected in the specific medium. The dielectric or DBR mirror may comprise more than two different layers. For example, a maximum number of layers may be 10. A typical layer thickness of the single layers may be 30 to 90 nm, e.g. approximately 50 nm.

The optoelectronic apparatus 20 of FIG. 2B comprises the same or corresponding components as the optoelectronic apparatus 20 of FIG. 1B. In addition, the dielectric layer 132, which has been explained with reference to FIG. 2A, is formed over the metal layer. In a similar manner as has been discussed above, the dielectric layer 132 may comprise a dielectric mirror.

The optoelectronic apparatus 20 of FIG. 2C comprises identical or corresponding components as the optoelectronic apparatus 20 of FIG. 1C. In addition, the dielectric layer 132, which has been explained with reference to FIG. 2A, is formed over the portions of the metal layer 130. In a similar manner as has been discussed above, the dielectric layer 132 may comprise a dielectric mirror.

According to embodiments, the optoelectronic apparatus illustrated in FIGS. 2A to 2C may be further modified by arranging the dielectric layer 132 also over portions of the first semiconductor layer 110. In this case, the dielectric layer may be optimized to be a high reflecting layer over the metal but an anti-reflecting layer above the semiconductor. According to further embodiments, separate dielectric layers may be used for covering the portions of the metal layer 130 and for covering portions of the first semiconductor layer 110.

FIG. 3A shows a vertical cross-sectional view of an optoelectronic apparatus 20 according to further embodiments. The optoelectronic apparatus 20 comprises an array of optoelectronic semiconductor devices 10. The optoelectronic apparatus comprises a semiconductor layer stack 105 comprising a first semiconductor layer 110 of a first conductivity type, e.g. n-type, an active zone 115 and a second semiconductor layer 120 of a second conductivity type, e.g. p-type.

The active zone 115 may, for example, comprise a pn junction, a double heterostructure, a single quantum well (SQW) structure or a multi quantum well (MQW) structure for generating radiation. In this context, the term “quantum well structure” has no meaning with regard to the dimensionality of the quantization. Thus, it includes, among other things, quantum wells, quantum wires and quantum dots, as well as any combination of these layers.

Adjacent optoelectronic semiconductor devices are separated by separating elements 125 that vertically extend through the semiconductor layer stack 105. The optoelectronic semiconductor devices 10 are configured to emit generated electromagnetic radiation 15 via a first main surface 111 of the first semiconductor layer 110. The optoelectronic apparatus 20 further comprises portions of a metal layer or first contact elements 136 arranged on a side of the first semiconductor layer 110 facing away from the active zone 115 and being arranged at positions of the separating elements 125.

The optoelectronic apparatus 20 may be arranged over a suitable carrier 100 that may be made of an insulating, conductive or semiconductor material. The separating elements 125 that are arranged between adjacent optoelectronic semiconductor devices may comprise a conductive body 126 and an insulating layer 129 insulating the conductive body 126 from the semiconductor layer stack 105. For example, the conductive body may comprise a separating metal layer 127. The separating metal layer 127 may e.g. comprise a transparent conductive oxide such as ITO (“Indium Tin Oxide”). The separating metal layer 127 may be arranged adjacent to the insulating layer 129. For example, the separating metal layer 127 may extend from a portion beneath the second semiconductor layer 120 to a region above the active zone 115. Horizontal portions of the separating metal layer may be electrically connected to the second semiconductor layer.

A material of the first and second semiconductor layers 110, 120 may comprise InₓGayAl_{1-x-y}P, with 0≤x≤1, 0≤y≤1, or GaN and InGaN.

A second current spreading layer 140 may be arranged over the carrier 100. The second current spreading layer 140 may be electrically connected to the second semiconductor layer 120 via the separating metal layer 127. Portions of the second current spreading layer 140 may form part of the conductive body 126 of the separating elements 125.

For example, the structure shown in FIG. 3A may be formed in a similar manner as has been explained above with reference to FIG. 1A.

The first current spreading layer 135 may be arranged over the first main surface 111 of the first semiconductor layer 110. The separating elements 125 may extend to the first current spreading layer 135. A horizontal upper portion of the insulating layer 129 may be adjacent to the first current spreading layer 135. The first current spreading layer 135 may be made of a transparent material such as a transparent conductive oxide.

Portions of a metal layer 136 are arranged on a side of the first semiconductor layer. For example, the metal layer may comprise a usually employed contact material such as AuGe, PdGe, Ag, Ag, etc. The metal layer may comprise several sub-layers. For example, the metal layer may further comprise a layer of transparent conducting oxide such as ITO below any of these contact materials. For example, a size of the single optoelectronic semiconductor devices 10 may be smaller than 10 μm.

The portions 136 of the conductive layer may implement first contact elements for electrically connecting the first current spreading layer 135. A height h of the first contact elements 136 may be arbitrary. For example, the height h of the first contact elements 136 may be smaller than 0.1*we, where we is the width of the emitting area of a light emitting portion.

FIG. 3B shows a vertical cross-sectional view of an optoelectronic apparatus 20 according to further embodiments. The optoelectronic apparatus 20 comprises a plurality of optoelectronic semiconductor devices 10. The optoelectronic apparatus 20 comprises similar or identical components as the optoelectronic apparatus illustrated in FIG. 3A. In addition, each of the optoelectronic semiconductor devices 10 further comprises a void 107 formed in the first main surface 111 of the first semiconductor layer 110. A vertical extension v of the void is larger than 0.75*t, wherein t denotes a layer thickness of the first semiconductor layer 150. In other words, the depth v of each of the voids may be large and the voids 107 may even extend to a position of the active zone 115. As a consequence, material of the first semiconductor layer is removed so as to reduce absorption. For example, a horizontal width w of the voids 107 may be smaller than a width c which may correspond to the smallest horizontal extension of the first or the second semiconductor layer 110, 120. For example, a horizontal width of the voids may be at least 1 μm. For example, a horizontal width of the voids may be smaller than 0.9*we, wherein we denotes the width of the light emitting area. A horizontal extension w of the void 107 may be selected by considering the trade-off between absorption and current spreading. The sidewalls of the void 107 do not need to be inclined with respect to a vertical direction, as is shown in FIG. 3B. According to further embodiments, the sidewalls of the void 107 may also be vertical. A width we of the emission portion e.g. the distance between neighboring separating elements 125 may be smaller than 100 μm or smaller, e.g. about 2 μm. Due to the formation of the voids, a portion of at least the first current spreading layer 135 is removed.

FIG. 3C shows a further vertical cross-sectional view of an optoelectronic apparatus comprising a plurality of optoelectronic semiconductor devices. Differing from the embodiments shown in FIG. 3B, a plurality of holes 108 are formed in the first main surface 111 of the first semiconductor layer 110. The holes may have a vertical extension v which is larger than 0.75*t, wherein t denotes a layer thickness of the first semiconductor layer.

The holes 108 may be identical or mutually different. For example, they may differ in depth, shape and/or width. Moreover, various fillings of the holes 108 will be described in the following. The fillings of the holes 108 may be identical or mutually different. For example, some of the holes 108 may be filled while others are not filled. According to further embodiments, the other holes may be filled with different materials. The distance between neighboring holes 108 may be identical or mutually different.

According to further embodiments, the semiconductor body including the holes 108 as e.g. illustrated in FIG. 3C may implement an ordered photonic structure 106. For example, the ordered photonic structure 106 may comprise a photonic crystal. According to further embodiments, the ordered photonic structure may also comprise a photonic quasicrystal. Furthermore, the ordered photonic structure may also comprise deterministic aperiodic structures.

Generally, in the context of the present disclosure, the term “ordered photonic structure” means a structure the structural elements of which are arranged at predetermined locations. The arrangement pattern of the structural elements is subject to a specific order. The functionality of the ordered photonic structure results from the arrangement of the structural elements. The structural elements are, for example, arranged such that diffraction effects occur. The structural elements may be arranged periodically, for example, so that a photonic crystal is realized. According to further embodiments, the structural elements may be arranged such that they represent deterministic aperiodic structures, for example Vogel spirals. According to further embodiments, the structural elements may be arranged such that they realize a quasi-periodic crystal, for example an Archimedean lattice.

FIG. 3D shows a horizontal cross-sectional view of the semiconductor device shown in FIG. 3B. The cross-sectional view is taken between I and I′as illustrated in FIG. 3C. As is shown, a plurality of semiconductor devices 10 are separated by separating elements 125. The conductive body 126 comprises separating metal layer 127. The separating elements 125 have the shape of a grid. As has been discussed above, the shape of the single optoelectronic semiconductor devices may be e.g. the shape of a square, a circle, a square having rounded corners, a hexagon or a hexagon having rounded corners. Likewise, the shape of the voids 107 may be e.g. the shape of a square, a circle, a square having rounded corners, a triangle, a hexagon or a hexagon having rounded corners. According to further embodiments, different shapes of the voids 107 are possible.

FIG. 3E shows a horizontal cross-sectional view of the optoelectronic apparatus shown in FIG. 3C. The cross-sectional view is taken between I and I′ as illustrated in FIG. 3C. As is shown, a plurality of holes 108 are arranged in the semiconductor layer 110 of each of the optoelectronic semiconductor devices 10. The shape of the holes may e.g. be a square shape, circular shape, rectangular shape or any other arbitrary shape.

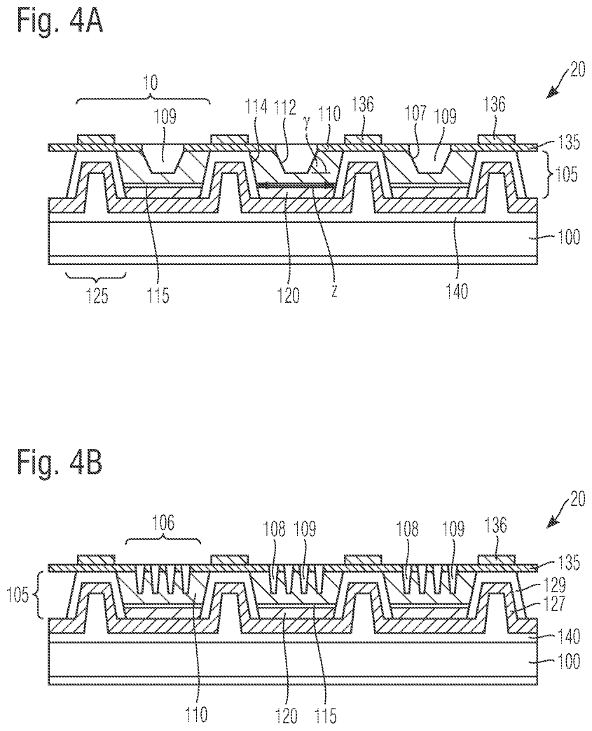

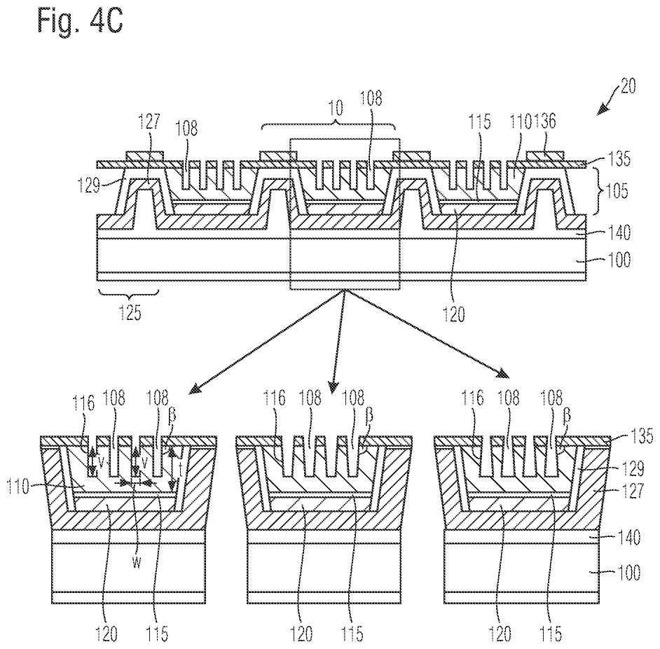

FIG. 4A shows a vertical cross-sectional view of an optoelectronic apparatus according to further embodiments.

Components of the optoelectronic semiconductor devices 10 may be identical or similar to those as have been discussed with reference to FIG. 3B. Differing from embodiments illustrated in FIG. 3B, the optoelectronic semiconductor devices further comprise a dielectric filling 109 which is formed in each of the voids 107. According to embodiments, the first current spreading layer 135 may be arranged over the voids 107. According to further embodiments, the first current spreading layer 135 may be removed from the portions directly above the voids 107. In this case absorption by the first current spreading layer 135 may be reduced.

According to embodiments, the dielectric filling 109 may have the same or a similar refractive index as the first semiconductor layer 110. As a result, the light extraction of this optoelectronic semiconductor device 10 may be similar to the light extraction of an optoelectronic semiconductor device without a void. For example, if GaN is taken as a material of the first semiconductor layer, Ti₂O₃ may be used as an index matched dielectric material 109.

According to further embodiments, the dielectric filling 109 may have a refractive index which is different from the refractive index of the adjacent semiconductor material.

Moreover, as is shown in FIG. 4A, the sidewall 112 of the void 107 does not need to be parallel to a sidewall 114 of the mesa. For example, an angle γ of the sidewall 112 with respect to a horizontal plane may be smaller than the angle between the sidewall 114 of the mesa with respect to the horizontal plane. For example, a difference may be at least 15°. Further, according to embodiments, a size of the cavity in the lowest part of the cavity 107 may be equal to or larger than ⅓*z, wherein z denotes a lateral width of the active zone.

When the dielectric filling 109 has a refractive index which is different from the refractive index of the adjacent semiconductor material, due to refraction and reduced absorption, the amount and direction of the emitted electromagnetic radiation may be changed.

FIG. 4B shows an optoelectronic device 20 which is similar to the optoelectronic device shown in FIG. 3C. Differing from embodiments illustrated in FIG. 3C, the dielectric filling 109 is filled in the holes 108. By way of example, the dielectric filling 109 may have a refractive index which may be similar to the refractive index of the first semiconductor layer 110 to provide similar light extraction properties. According to further embodiments, in a similar manner as has been discussed with reference to FIG. 4A, the dielectric filling 109 may have a refractive index which is different from the refractive index of the first semiconductor layer. As a result, the amount and directionality of the emitted electromagnetic radiation 15 may be changed.

According to further embodiments, the semiconductor body including the holes 108 which are employed according to embodiments shown in FIG. 4B may comprise an ordered photonic structure 106, e.g. a photonic crystal or deterministic aperiodic structures. The ordered photonic structure may change the amount and directionality of the emitted electromagnetic radiation. Further, the ordered photonic structure may provide a high contrast between adjacent optoelectronic semiconductor devices 10.

FIG. 4C illustrates further modifications of the holes 108 shown in FIG. 3C and 4B. As is shown, the holes 108 may extend to a depth v which may be larger than 0.75*t which corresponds to the layer thickness of the first semiconductor layer. As is illustrated in the left-hand portion of FIG. 4C, an angle β of sidewalls 116 of the holes 108 with respect to a horizontal plane may be e.g. approximately 90°. In other words, the sidewalls 116 of the holes 108 may extend in a substantially vertical direction. Accordingly, the diameter of the holes 108 does not substantially change with decreasing distance from the active zone 115.

According to further modifications, the angle β may be larger than 90°, as is illustrated in the middle portion of FIG. 4C. Hence, the diameter of the hole 108 decreases with decreasing distance from the active zone 115.

As is illustrated in the right-hand portion of FIG. 4C, the angle β between the sidewall 116 of the hole 108 and a horizontal plane may be smaller than 90°. As a result, the diameter of the holes 108 becomes larger with decreasing distance from the active zone 115.

When the plurality of holes 108 that may optionally extend to the active zone 115 are to be formed, it is possible to grow the first semiconductor layer using a SAG (“Selective Area Growth”) epitaxy method. According to further embodiments, the semiconductor layer may be grown and subsequently be etched.

The design of the holes (e.g. width, depth, sidewall slope) may be optimized for directionality and emission enhancement. The specific design may be tuned by correspondingly tuning the lithography and etching method. For example, the dry etching parameters may be appropriately selected. Further, it is possible to selectively etch the crystal facets. According to further embodiments, an epitaxial process, e.g. a SAG epitaxial process may be appropriately tuned.

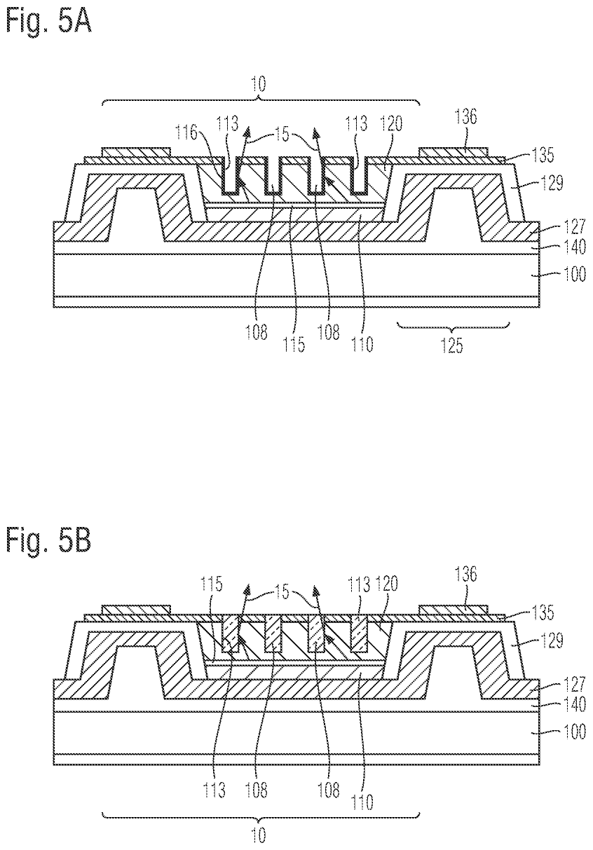

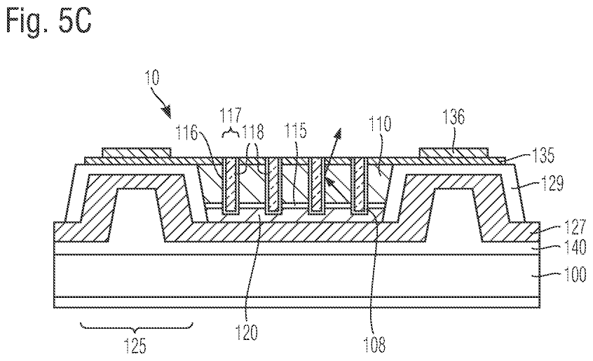

According to further embodiments, a modification material 113 which may substantially change the optical properties of the first semiconductor layer 110 may be arranged in the holes 108. For example, as is illustrated in FIG. 5A, the modification material 113 may be a lining material which covers the sidewalls 116 of the holes 108 without filling the holes 108. For example, the modification material may be a dielectric layer having a different refractive index than the first semiconductor layer 110. Due to the presence of the modification material 113, the outcoupling and directionality may be improved and crosstalk between neighboring optoelectronic semiconductor devices may be reduced. According to further embodiments, the modification material 113 may be a transparent conductive oxide. As a result, the current flow may be improved.

According to further embodiments, as is shown in FIG. 5B, the modification material 113 may be a filling. The modification material 113 may be, in a similar manner as has been discussed above, a dielectric material having a different refractive index than the first semiconductor layer 110. As a result, the outcoupling and directionality may be improved. Further, crosstalk between neighboring optoelectronic semiconductor devices 10 may be reduced. According to further embodiments, the modification material 113 may comprise a transparent conductive oxide and may be implemented as a filling.

Generally, the layer thickness and the material of the modification material 113 may be optimized for the desired emission angle, emission enhancement and other properties such as spreading.

FIG. 5C shows a cross-sectional view of an optoelectronic semiconductor device 10 according to further embodiments. In addition to elements previously described, the optoelectronic semiconductor device 10 comprises a reflecting material 117 that is arranged in the holes 108. As is illustrated in FIG. 5C, the reflecting material 117 may be implemented by a dielectric or DBR mirror 118 which is arranged on the sidewall 116 of the hole and further a metal filling filled in the holes 108.

Due to the implementations shown in FIG. 5C, the outcoupling may be improved. Further, by tailoring dimensions of the substructure, guided modes may be enhanced. For example, the holes including the reflecting material may extend to the active zone 115 or even to the second semiconductor layer 120. This can be achieved by a bottom-up approach such as by growing semiconductor nanorods or nanofins with embedded active regions. Hence, according to embodiments, a waveguiding effect may be provided. As a result, directional upward emission may be accomplished. Further, crosstalk may be reduced and current flow may be optimized. The person skilled in the art will appreciate that design and materials of the reflecting material 117 may be optimized for enhancing the above-described effects.

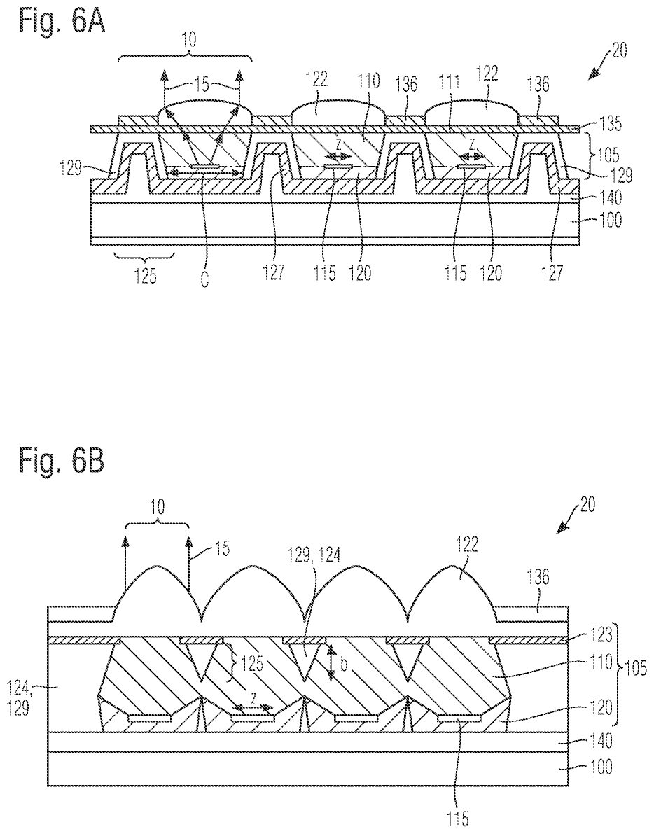

FIG. 6A shows a vertical cross-sectional view of an array of optoelectronic semiconductor devices 10 according to further embodiments. An optoelectronic semiconductor device 10 comprises a semiconductor layer stack 105 comprising a first semiconductor layer 110 of a first conductivity type, a second semiconductor layer 120 of a second conductivity type and an active zone 115. The optoelectronic semiconductor device is configured to emit generated electromagnetic radiation 15 via a first main surface 111 of the first semiconductor layer 110. A lateral width z of the active zone 115 is smaller than the smallest lateral width c of the first and the second semiconductor layers.

As is shown in FIG. 6A, the lateral width of the semiconductor layers increases with increasing distance from the carrier 100. Accordingly, the smallest lateral width of the first and the second semiconductor layers corresponds to the lateral width c of the second semiconductor layer 120 at a bottom portion, i.e. on a side adjacent to the carrier 100. According to embodiments described with reference to FIGS. 6A and 6B, a lateral width of the active zone is substantially smaller than e.g. the pixel emission aperture. In other words, the emission portion within the semiconductor layer stack 105 may be regarded as a point-like emitter.

The further components of the semiconductor device illustrated in FIGS. 6A and 6B are similar to those discussed herein before. For example, a semiconductor layer stack 105 in which the active zone 115 has a smaller width than a width of the first and second semiconductor layers may be formed by forming an active zone having a horizontal width that corresponds to a width of the adjacent first or second semiconductor layer. A photolithographic step is performed, followed by etching the active zone 115 so as to reduce the width z of the active zone 115. Thereafter, a further epitaxial method is employed so as to grow the second semiconductor layer 120 or the first semiconductor layer 110. As a result, an active zone 115 having a substantially smaller lateral width than the adjacent semiconductor layers and being embedded in the semiconductor layer stack 105 is formed.

The optoelectronic semiconductor device 10 shown in FIG. 6A further comprises a lens 122 that is formed over the first current spreading layer 135 and over the first main surface 110 of the first semiconductor layer. The lens 122 may have such a shape that the active zone 115 is arranged at a position of a focal point of the lens 122. For example, according to embodiments that are illustrated in FIG. 6A, the first current spreading layer 135 may comprise InGaAlP. When manufacturing the array of optoelectronic semiconductor devices, a further transparent InAlP-layer may be formed over the first current spreading layer 135. Then, the InAlP-layer may be etched to form the micro-lenses 122. For example, the shape of the micro-lenses 122 may be optimized for collimation taking into account the desired amount of light in the cone of interest. The shape may be tailored by adjusting the shape of the photoresist covering the material layer for forming the micro-lenses and by varying the dry etching conditions. The shape of the photoresist material may be varied by varying the processing conditions.

Another method may comprise etching the micro-lenses by wet etching first using a resist mask until the InGaAlP layer has been reached. Thereafter, the etching process may be continued after removal of the photoresist mask, to produce the desired curvature of the InAlP lens and, thus, to form a microlens.

According to further embodiments, the micro-lenses may be formed of a material having a refractive index which is matched to the material of the semiconductor layer. For example, in case of using a GaN semiconductor material the lenses may be formed of TiOx.

FIG. 6B shows an example of an array of optoelectronic semiconductor devices 10. According to embodiments illustrated in FIG. 6B, the semiconductor material may comprise GaN and the micro-lenses may be formed of e.g. TiOx so as to obtain an index matched material. For example, the separating elements 125 between adjacent semiconductor devices 10 do not comprise a conductive body as was the case e.g. in FIG. 6A. Instead, the separating elements 125 may comprise an insulating material 129 and/or a void 124 only. For example, the optoelectronic apparatus 20 shown in FIG. 6B may be formed by epitaxially growing the first and the second semiconductor layer 110, 120 as well as the active zone 115 over a growth substrate (not illustrated).

Portions of a dielectric layer 123, e.g. SiO₂ are arranged over the growth substrate so as to insulate adjacent optoelectronic semiconductor devices 10. Using this method, first the first semiconductor layer is grown, followed by the active zone 115. After patterning the active zone 115, the second semiconductor layer 120 is epitaxially grown. According to this method, no semiconductor material is grown over portions of the growth substrate that are covered by the portions of the dielectric layer 123. After forming the second current spreading layer 140 over the carrier 100 and attaching these to the semiconductor layer stack 105, the growth substrate is removed so as to expose the dielectric layer 123. Thereafter, a material for forming the micro-lenses, e.g. TiOx is formed over a resulting surface. The material layer is patterned to form a plurality of micro-lenses 122 and a first contact element 136 is formed over a resulting surface.

As has been described above, by e.g. forming portions of a metal layer over the emission surface, forming voids in the first semiconductor layer and/or forming lenses over the light emitting portions and reducing a width of the active zone 115, micro LEDs having a greatly improved directionality may be provided. For example, the material of the lenses may be or comprise a material of the semiconductor layers. According to further embodiments, the material of the lenses may be different from the material of the semiconductor layers.

An optoelectronic apparatus comprising an array of optoelectronic semiconductor devices as has been described above may e.g. be employed as a Virtual Reality display, an Augmented Reality Display or a general projection device.

For such applications, each individual micro LED in the array may be made individually addressable, by means of individual p- or n-contacts, for example.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

1.-23. (canceled)

24. An optoelectronic semiconductor device comprising:
a semiconductor layer stack comprising a first semiconductor layer of a first conductivity type, an active zone, and a second semiconductor layer of a second conductivity type,
wherein the optoelectronic semiconductor device is configured to emit generated electromagnetic radiation via a first main surface of the first semiconductor layer, and
wherein a lateral width z of the active zone is smaller than a smallest lateral width c of the first and the second semiconductor layers;
separating elements arranged adjacent to the semiconductor layer stack, the separating elements vertically extending along the semiconductor layer stack; and
portions of a metal layer arranged on a side of the first semiconductor layer facing away from the active zone and arranged at positions of the separating elements.

25. The optoelectronic semiconductor device according to claim 24, wherein the lateral width of the active zone is smaller than 0.3*c, and wherein c denotes the smallest lateral width of the first semiconductor layer.

26. The optoelectronic semiconductor device according to claim 24, further comprising a lens arranged above the first main surface of the first semiconductor layer, wherein a focal point of the lens is arranged at a position of the active zone.

27. An optoelectronic apparatus comprising:
an array of optoelectronic semiconductor devices comprising a semiconductor layer stack comprising a first semiconductor layer of a first conductivity type, an active zone, and a second semiconductor layer of a second conductivity type,
wherein adjacent optoelectronic semiconductor devices are separated by separating elements vertically extending through the semiconductor layer stack,
wherein the optoelectronic semiconductor devices are configured to emit generated electromagnetic radiation via a first main surface of the first semiconductor layer, and
wherein portions of a metal layer are arranged on a side of the first semiconductor layer facing away from the active zone and are arranged at positions of the separating elements, a horizontal extension of the portions of the metal layer increasing with increasing distance from the first main surface.

28. The optoelectronic apparatus according to claim 27, wherein the separating elements comprise a conductive body and an insulating layer insulating the conductive body from the semiconductor layer stack, and wherein a largest horizontal extension of the portion of the metal layer is larger than or equal to a smallest horizontal extension of the conductive body.

29. The optoelectronic apparatus according to claim 27, wherein the metal layer is a horizontal metal layer.

30. The optoelectronic apparatus according to claim 27, wherein the metal layer comprises silver or gold.

31. The optoelectronic apparatus according to claim 27, further comprising a dielectric layer arranged over sidewalls of the portion of the metal layer.

32. The optoelectronic apparatus according to claim 27, wherein a thickness of the metal layer is larger than 0.1*we, wherein we is a width of an emitting area of at least one of the optoelectronic semiconductor devices.

33. An optoelectronic semiconductor device comprising:
a semiconductor layer stack comprising a first semiconductor layer of a first conductivity type, an active zone, and a second semiconductor layer of a second conductivity type;
separating elements arranged adjacent to the semiconductor layer stack, the separating elements vertically extending along the semiconductor layer stack,
wherein the optoelectronic semiconductor device is configured to emit generated electromagnetic radiation via a first main surface of the first semiconductor layer;
portions of a metal layer arranged on a side of the first semiconductor layer facing away from the active zone and arranged at positions of the separating elements; and
a void or a plurality of holes formed in the first main surface of the first semiconductor layer,
wherein a vertical extension v of the void or the plurality of holes is larger than 0.75*t, and
wherein t denotes a layer thickness of the first semiconductor layer.

34. The optoelectronic semiconductor device according to claim 33, wherein each of the separating elements comprises a conductive body insulated from the semiconductor layer stack by a dielectric layer.

35. The optoelectronic semiconductor device according to claim 33, further comprising a dielectric filling arranged in the void or in at least one of the plurality of holes.

36. The optoelectronic semiconductor device according to claim 33, further comprising a transparent conductive oxide material filled in the void or in at least one of the plurality of holes.

37. The optoelectronic semiconductor device according to claim 33, wherein the semiconductor layer stack is patterned to form a mesa, and wherein an angle of a sidewall of the void with respect to a horizontal direction is smaller than an angle of a sidewall of the mesa with respect to the horizontal direction.

38. The optoelectronic semiconductor device according to claim 33, further comprising a reflecting material arranged in at least one of the holes.

39. The optoelectronic semiconductor device according to claim 38, wherein the reflecting material comprises a dielectric mirror layer arranged on sidewalls of at least one of the holes.

40. The optoelectronic semiconductor device according to claim 38, wherein the reflecting material comprises a metal.
